(19) United States
(12) Patent Application Publication
(10) Pub. No.: US 2025/0211197 A1
(43) Pub. Date: Jun. 26, 2025

(54) RESONATOR WITH A COMMON REFLECTOR

(71) Applicant: WISOL CO., LTD., Osan-si (KR)

(72) Inventors: Kensei UEHARA, Osan-si (KR); Jin Hong JEONG, Osan-si (KR); Takahiro SATO, Osan-si (KR); Dong Kwan LEE, Osan-si (KR)

(73) Assignee: WISOL CO., LTD., Osan-si (KR)

(21) Appl. No.: 18/984,378

(22) Filed: Dec. 17, 2024

(30) Foreign Application Priority Data
Dec. 21, 2023 (KR) 10-2023-0188820

(51) Int. Cl. H03H 9/02; H03H 9/145; H03H 9/25

(52) U.S. Cl. CPC H03H 9/02637; H03H 9/02992; H03H 9/145; H03H 9/25

(57) ABSTRACT

Provided is a resonator with a common reflector, and more specifically, to a resonator with a common reflector in a surface acoustic wave (SAW) device having multiple resonators, where a reflector of one resonator is shared with the reflector of another resonator. By forming a common reflector, the area required for resonator formation on the substrate can be reduced.

### BACKGROUND OF THE INVENTION

### Field of the Invention

The present invention relates to a resonator with a common reflector, and more specifically, it concerns a resonator in a surface acoustic wave device having multiple resonators, where a common reflector is formed by sharing the reflector of one resonator with the reflector of another resonator, thereby reducing the area required for resonator formation on the substrate.

### Background of the Related Art

Surface Acoustic Waves (SAW) refer to waves that propagate along the surface of an elastic solid. These elastic surface waves concentrate energy near the surface as they propagate and are classified as mechanical waves. Surface Acoustic Wave devices are electromechanical devices that utilize the interaction between these surface acoustic waves and semiconductor conduction electrons, using surface acoustic waves transmitted to the surface of a piezoelectric crystal. These devices can have a wide range of industrial applications, such as sensors, oscillators, and filters, and offer various advantages, including miniaturization, lightweight, robustness, stability, sensitivity, low cost, and real-time performance.

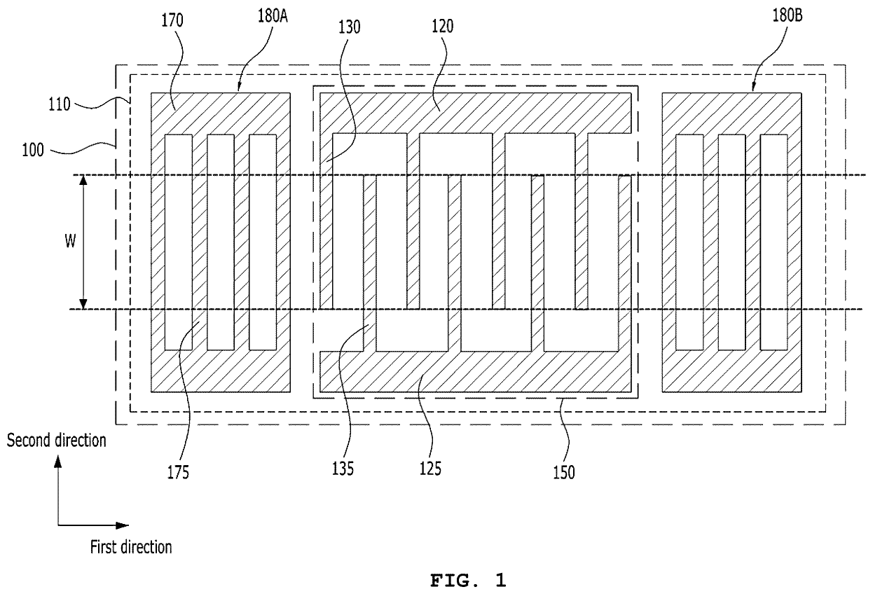

FIG. 1 shows a plan view of a resonator.

Referring to FIG. 1, the resonator is configured by forming an IDT (Inter Digital Transducer) electrode part (150) on a piezoelectric substrate (100), which converts an electrical signal into surface acoustic waves on the surface of the piezoelectric substrate (100). Reflectors (180A, 180B) are formed at both ends of the IDT electrode part (150) to prevent the surface acoustic wave energy generated by the IDT electrode part (150) from leaking or damping, thereby trapping the surface acoustic wave energy within the IDT electrode part (150).

The IDT electrode part (150) includes a first and a second busbars (120, 125) that extend in the first direction and are spaced in the second direction perpendicular to the first direction, and a first and a second IDT electrodes (130, 135) that alternately extend in the second direction from the first and second busbars (120, 125) and are spaced in the first direction.

The reflectors (180A, 180B) include a pair of reflector busbars (170) that extend in the first direction and are spaced in the second direction perpendicular to the first direction, and a plurality of reflector electrodes (175) that extend from the reflector busbars (170) in the second direction and are spaced in the first direction.

A surface acoustic wave filter used in electronic devices can be constructed with one or more connected resonators (110).

When constructing a surface acoustic wave filter with multiple resonators (110), reflectors (180A, 180B) must be formed on each resonator (110), which increases the space occupied by the piezoelectric substrate (100), thus limiting the miniaturization of the surface acoustic wave filter.

Therefore, there is a need for a technology that can reduce the size of the surface acoustic wave resonator or filter while maintaining its performance.

### SUMMARY OF THE INVENTION

The technical problem to be solved by the present invention is to provide a resonator with a common reflector, which allows for the miniaturization of a surface acoustic wave resonator or surface acoustic wave filter by reducing the area occupied by the reflector, which is formed at both ends of the IDT electrode part to trap surface acoustic wave energy within the IDT electrode part, on the piezoelectric substrate.

The technical problems of the present invention are not limited to those mentioned above, and other technical problems that are not mentioned will be clearly understood by those skilled in the art from the description below.

The resonator with a common reflector of the present invention, which aims to solve the above-mentioned technical problem, is formed on a piezoelectric substrate, and includes a first and a second IDT electrode parts that are formed side by side in the first direction, a common reflector formed between the first and the second IDT electrode parts, which is shared by both the first and the second IDT electrode parts, and a first and a second reflectors formed on the opposite sides of the common reflector, parallel to the first and the second IDT electrode parts.

In some embodiments of the present invention, if the number of reflector electrodes of the first IDT electrode part before the common reflector is formed is denoted as N1, and the number of reflector electrodes of the second IDT electrode part is denoted as N2, the number of reflector electrodes Ns of the first common reflector can satisfy the following condition:

$$Min ( N 1 , N 2 ) \leq Ns \leq ( N 1 + N 2 )$$

In some embodiments of the present invention, if the second direction length of the reflector of the first IDT electrode part before the formation of the common reflector is denoted as H1, and the second direction length of the reflector of the second IDT electrode part is denoted as H2, and the second direction length of the common reflector is denoted as HS, the following condition can be satisfied:

Max(H1,H2)≤HS

In some embodiments of the present invention, if the distance between the IDT electrodes of the first IDT electrode part is denoted as T1, and the distance between the IDT electrodes of the second IDT electrode part is denoted as T2, the distance between the reflector electrodes of the common reflector, denoted as TS1, can satisfy the following condition:

Max(T1,T2)≤TS1

The resonator with a common reflector of the present invention, which aims to solve the above-mentioned technical problem, is formed on a piezoelectric substrate, and includes a first to a nth IDT electrode parts (where n is a natural number greater than or equal to 3) that are formed side by side in the first direction, first to n−1 common reflectors that are shared between adjacent pairs of the first to the nth IDT electrode parts, and a first and a nth reflectors formed on the opposite sides of the common reflector, parallel to the first and nth IDT electrode parts.

In some embodiments of the present invention, if the number of reflector electrodes of the (n−1)th IDT electrode part before the formation of the (n−1)th common reflector is denoted as Nn−1, and the number of reflector electrodes of the nth IDT electrode part is denoted as Nn, the number of reflector electrodes Ns of the (n−1)th common reflector can satisfy the following condition:

$$Min ( Nn - 1 , Nn ) \leq Ns \leq ( Nn - 1 + Nn )$$

In some embodiments of the present invention, if the second direction length of the reflector of the (n−1)th IDT electrode part before the formation of the (n−1)th common reflector is denoted as Hn−1, and the second direction length of the reflector of the nth IDT electrode part is denoted as Hn, and the second direction length of the (n−1)th common reflector is denoted as HSn−1, the following condition can be satisfied:

$$Max ( Hn - 1 , Hn ) \leq HSn - 1$$

In some embodiments of the present invention, if the distance between the IDT electrodes of the (n−1)th IDT electrode part is denoted as Tn−1, and the distance between the IDT electrodes of the nth IDT electrode part is denoted as Tn, the distance between the reflector electrodes of the common reflector, denoted as TSn−1, can satisfy the following condition:

$$Max ( Tn - 1 , Tn ) \leq TSn - 1$$

In some embodiments of the present invention, the electrode part may include a first and a second busbars extend in the first direction and are spaced in the second direction perpendicular to the first direction, and first and second IDT electrodes that alternately extend in the second direction from the first and the second busbars and are spaced in the first direction.

In some embodiments of the present invention, the reflector may include a pair of reflector busbars that extend in the first direction and are spaced in the second direction perpendicular to the first direction, and a plurality of reflector electrodes that extend in the second direction and are spaced in the first direction.

The resonator with a common reflector according to the present invention forms a common reflector by sharing the reflector of one resonator with the reflector of another resonator in a surface acoustic wave device having multiple resonators. This allows the number of reflectors formed in two resonators, which would normally be four, to be reduced to three, and the number of reflectors formed in n resonators, which would normally be 2n, to be reduced to n+1. As a result, the area required for resonator formation on the substrate is reduced by using a resonator with a common reflector.

FIG. 1 is a plan view of a single resonator.

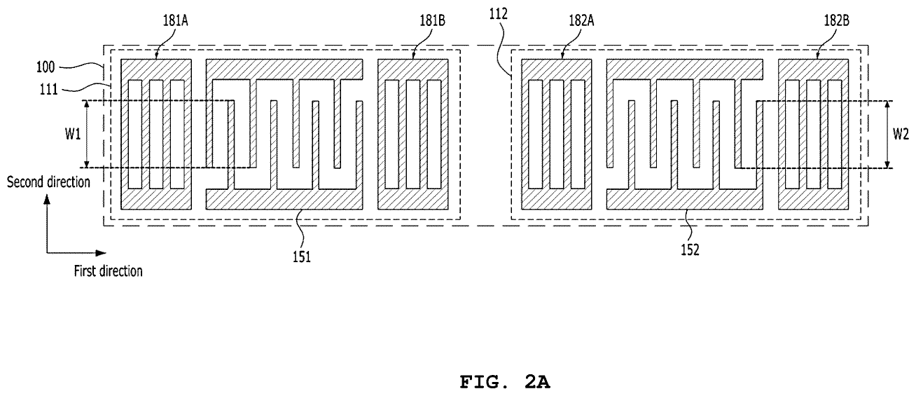

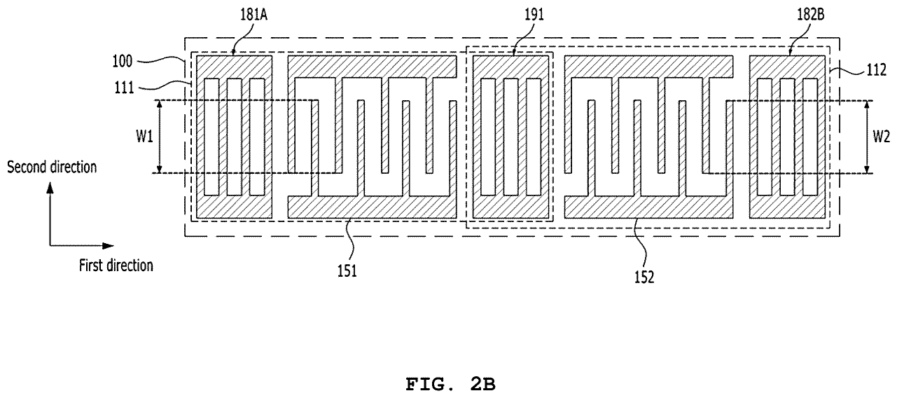

FIGS. 2A and 2B are plan views showing a surface acoustic wave resonator according to an embodiment of the present invention.

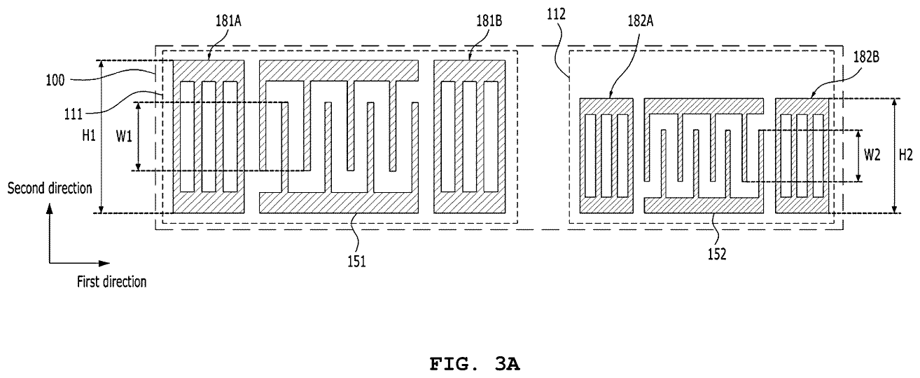

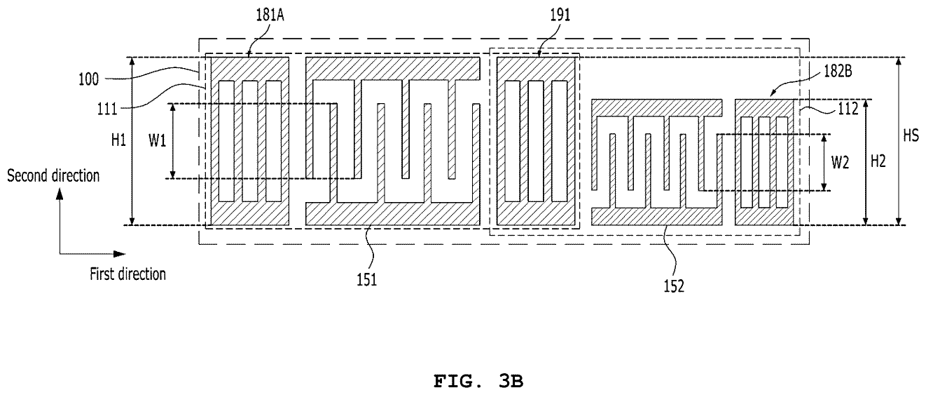

FIGS. 3 A and 3B are plan views showing a surface acoustic wave resonator in the case where the aperture is different according to an embodiment of the present invention.

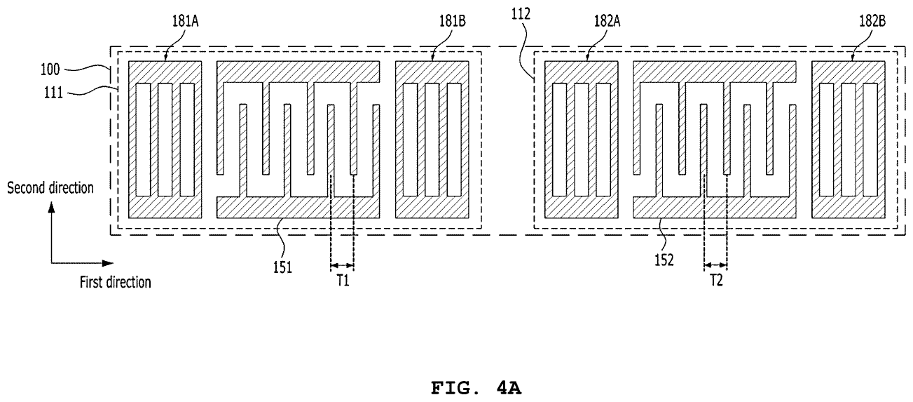

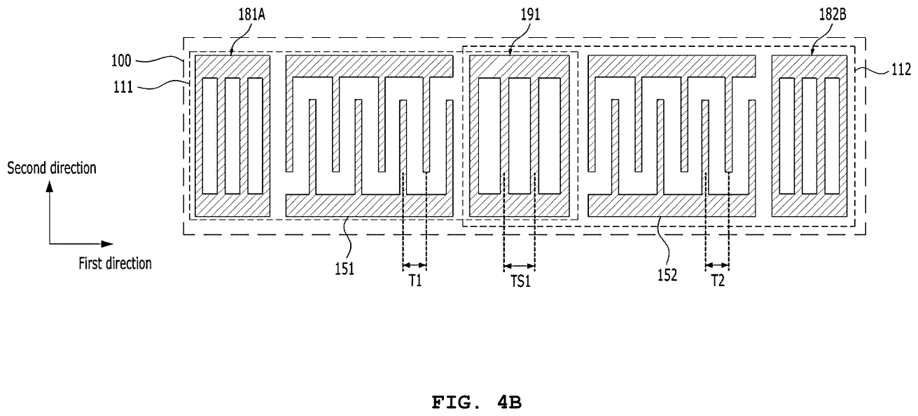

FIGS. 4A and 4B are plan views showing a surface acoustic wave resonator in the case where the distance between the electrodes is different according to an embodiment of the present invention.

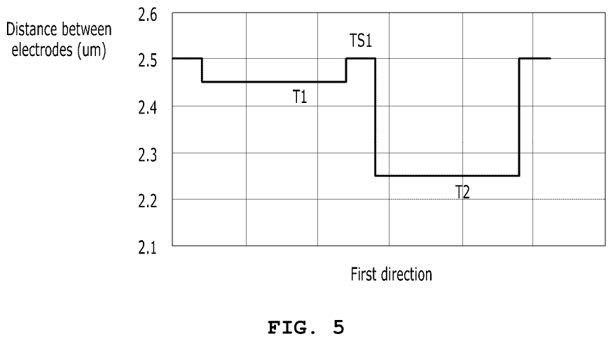

FIG. 5 is a diagram showing the distance between the electrodes according to FIGS. 4A and 4B.

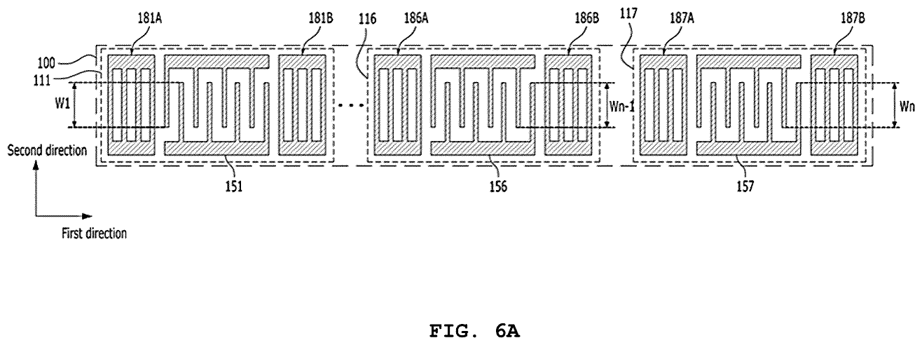

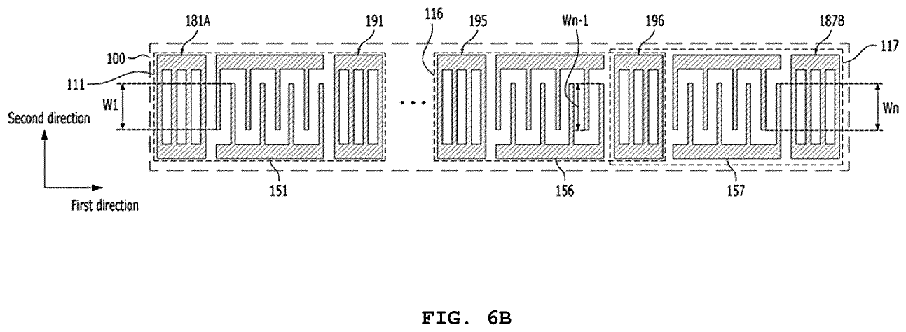

FIGS. 6A and 6B are plan views showing a surface acoustic wave resonator according to another embodiment of the present invention.

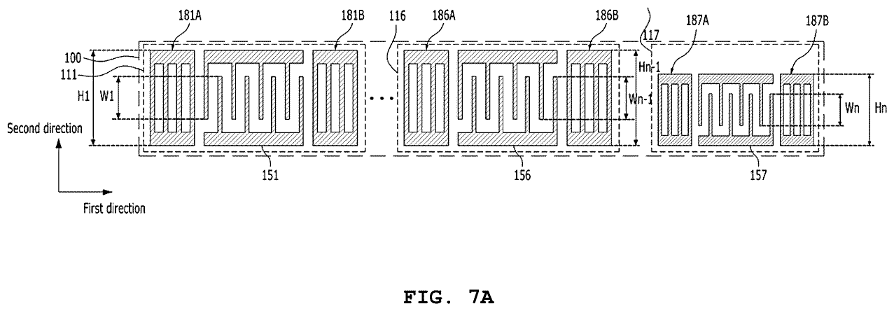

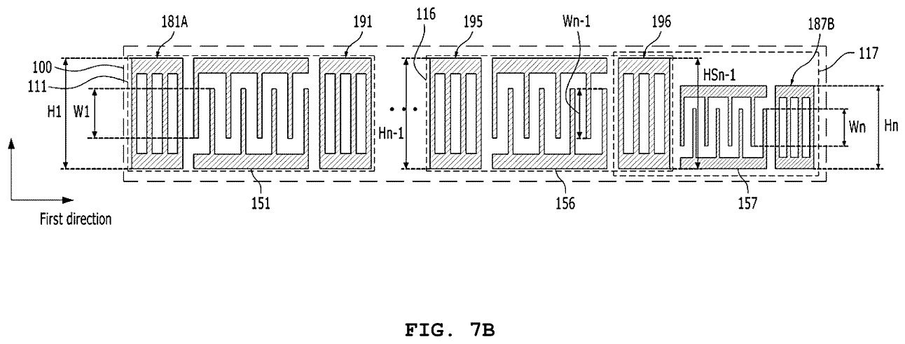

FIGS. 7A and 7B are plan views showing a surface acoustic wave resonator in the case where the aperture is different according to another embodiment of the present invention.

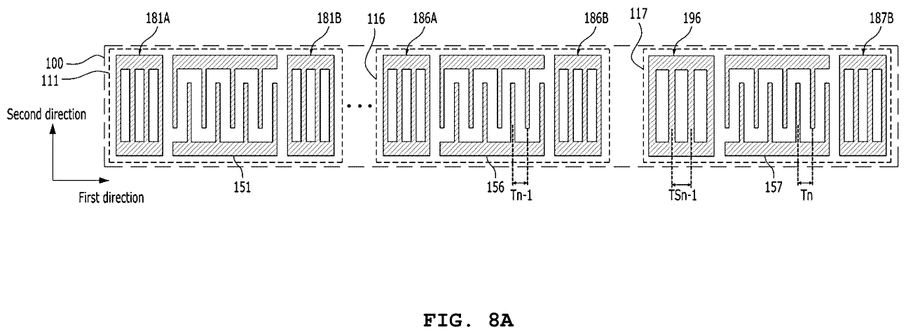

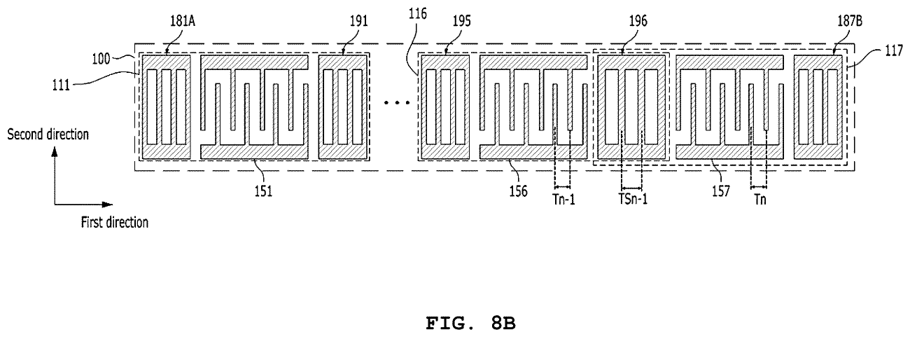

FIGS. 8A and 8B are plan views showing a surface acoustic wave resonator in the case where the distance between the electrodes is different according to another embodiment of the present invention.

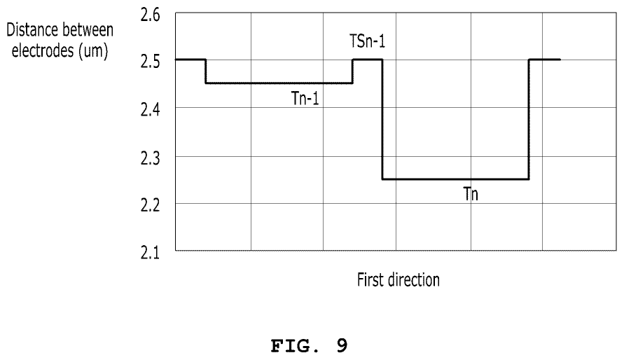

FIG. 9 is a diagram showing the distance between the electrodes according to FIGS. 8A and 8B.

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

In addition, throughout the specification, when a part is said to be “connected” to another part, this also includes “indirectly” or “electrically connected” cases with intervention of other members or components therebetween, as well as “directly connected” cases.

In addition, throughout the specification, the description that each layer (film), region, pattern, or structure is formed “above/on” or “beneath/under” a substrate, each layer (film), region, pad, or pattern includes both cases that they are formed directly and formed with intervention of other layers. The criteria for being above/on or beneath/under each layer are explained with reference to the drawings.

In addition, expressions such as ‘first, second’, and the like are only used to distinguish a plurality of components, and do not limit the sequence of the components or other features.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

The present invention will be described in detail with reference to the drawings.

FIGS. 2A and 2B are plan views showing a surface acoustic wave resonator according to an embodiment of the present invention, where FIG. 2A shows two resonators each formed separately, and FIG. 2B shows the two resonators sharing a common reflector.

Referring to FIG. 2B, the surface acoustic wave resonator according to an embodiment of the present invention is formed on a piezoelectric substrate (100) and includes a first and a second IDT electrode parts (151, 152) formed side by side in the first direction. Between the first and the second IDT electrode parts (151, 152), a common reflector (191) is formed, which is shared by the first and the second IDT electrode parts (151, 152). Additionally, a first and a second reflectors (181A, 182B) are formed on the opposite side of the common reflector (191), parallel to the first and the second IDT electrode parts (151, 152).

The piezoelectric substrate (100) may be a multilayer substrate including multiple layers. The multiple layers may include, for example, a supporting substrate made of silicon and a piezoelectric layer comprising materials such as LiTaO₃ (LT) or LiNbO₃ (LN) located at the top.

The IDT electrode part (150) includes a first and a second busbars (120, 125) that extend in the first direction and are spaced in the second direction perpendicular to the first direction, and a first and a second IDT electrodes (130, 135) that extend alternately in the second direction from the first and the second busbars (120, 125) and are spaced in the first direction.

The reflector may include a pair of reflector busbars (170) that extend in the first direction and are spaced from each other in the second direction perpendicular to the first direction, and a plurality of reflector electrodes (175) that extend in the second direction and are spaced from each other in the first direction. Each of the reflector busbars may extend integrally as a whole or may extend while including some sections that are cut off.

The first and the second IDT electrode parts (151, 152) and the reflectors (181A, 182B, 191) can be formed into a single metal film or a stacked metal film and may be formed simultaneously by the same process, such as a deposition process.

Referring to FIG. 2A, the first reflector (181B) in the first direction of the first IDT electrode part (151) and the second reflector (181A) in the first direction of the second IDT electrode part (152) are separately formed on the piezoelectric substrate (100). However, referring to FIG. 2B, the first reflector (181B) and the second reflector (181A) are shared and combined to form a single first common reflector (191). This allows for a reduction in the area of the piezoelectric substrate (100) by the area of one reflector.

In this case, before forming the common reflector, if the number of electrodes of the first reflector (181B) in the first IDT electrode part (151) is denoted as N1 and the number of electrodes of the second reflector (182A) in the second IDT electrode part (152) is denoted as N2, the number of electrodes of the first common reflector (191), Ns, may satisfy the following condition:

$$Min ( N 1 , N 2 ) \leq Ns \leq ( N 1 + N 2 )$$

That is, the number of electrodes of the common reflector can be equal to or greater than the smaller number of electrodes of the two reflectors placed on either side, and can be equal to or less than the sum of the number of electrodes of both reflectors.

By forming the reflectors in this manner, when measuring the characteristics of the resonator, such as frequency characteristics and insertion loss, it can be confirmed that the characteristics do not degrade even when the reflectors are shared.

FIGS. 3A and 3B are plan views showing a surface acoustic wave resonator in the case where the apertures are different according to an embodiment of the present invention. FIG. 3A shows two resonators formed separately, and FIG. 3B shows the two resonators sharing a common reflector.

Referring to FIGS. 3A and 3B, before forming the common reflector (191), let the second direction length of the reflector (181A, 181B) of the first electrode part (151) be H1 and the second direction length of the reflector (182A, 182B) of the second IDT electrode part (152) be H2. Then, the second direction length HS of the common reflector (191) satisfies the condition:

Max(H1,H2)≤HS

That is, when the two resonators have different apertures, the length of the common reflector is larger than or equal to the length of the reflector of the resonator with the larger aperture.

The aperture is the region where the first and the second IDT electrodes (130, 135) intersect. This region is crucial because surface acoustic waves primarily propagate through it, determining the characteristics of the resonator. If the aperture is large, the length of the IDT electrode part and the reflector in the second direction increases proportionally.

By forming the resonators in this manner, measurements of the resonator's characteristics, such as frequency characteristics and insertion loss, show that sharing the reflectors does not degrade the characteristics.

FIGS. 4A and 4B are plan views showing a surface acoustic wave resonator with different electrode distances according to an embodiment of the present invention. FIG. 4A shows two resonators formed separately, and FIG. 4B shows the two resonators sharing a common reflector.

Referring to FIG. 4B, let the distance between the IDT electrodes (130, 135) in the first IDT electrode part (151) be T1 and the distance between the IDT electrodes (130, 135) in the second IDT electrode part (152) be T2, then, the distance between the reflector electrodes of the first common reflector (191), denoted as TS1, satisfies the condition:

Max(T1,T2)≤TS1

That is, the distance between the electrodes of the common reflector is greater than or equal to the larger of the distances between the two IDT electrodes.

FIG. 5 shows the electrode distance as depicted in FIGS. 4A and 4B.

Referring to FIG. 5, it can be confirmed that the distance between the electrodes of the first common reflector (191), TS1, is greater than the larger of the distances between the electrodes of the first IDT electrode part (151) and the second IDT electrode part (152), T1 and T2.

By forming the resonators in this manner, when measuring the resonator's frequency characteristics and insertion loss, it is confirmed that sharing the reflectors does not degrade the characteristics.

Another embodiment of the present invention will be described with reference to the drawings.

FIGS. 6A and 6B are plan views showing a surface acoustic wave resonator according to another embodiment of the present invention. FIG. 6A shows that n resonators are formed separately, and FIG. 6B shows that the n resonators share a common reflector.

Referring to FIG. 6B, the surface acoustic wave resonator according to another embodiment of the present invention is formed on a piezoelectric substrate (100) and includes a first to a n-th IDT electrode parts (151 . . . 157) that are arranged in parallel in the first direction, a first to a (n−1)-th common reflectors (191-196) formed between every adjacent two IDT electrode parts of the first to the n-th IDT electrode parts (151 . . . 157) and shared between adjacent pairs of IDT electrode parts. The resonator also includes a first and a n-th reflectors (181A, 187B) formed parallel to the first and the n-th IDT electrode parts (151, 157) on the opposite side of the common reflectors. Here, n is a natural number greater than or equal to 3.

The piezoelectric substrate (100) may be a multilayer substrate that includes multiple layers. For example, the multiple layers may consist of a supporting substrate made of silicon and a piezoelectric layer located on top, which may include materials such as LiTaO₃ (LT) or LiNbO₃ (LN).

Each of the first to the n-th IDT electrode parts (151, 157) may include a first and a second busbars (120, 125) that extend in the first direction and are spaced in the second direction perpendicular to the first direction, and a first and a second IDT electrodes (130, 135) extending alternately in the second direction and spaced in the first direction.

The reflector includes a pair of reflector busbars (170) that extend in the first direction and are spaced in the second direction perpendicular to the first direction, a plurality of reflector electrodes (175) that extend in the second direction and are spaced in the first direction.

The first to n-th IDT electrode parts (151 . . . 157) and the reflectors (181A, 182B, 191) can be formed into a single metal layer or laminated metal layers. They can be simultaneously formed by the same process, such as a deposition process.

Referring to FIG. 6A, a left first reflector (181A) and a right first reflector (181B) are formed on both sides of the first IDT electrode part (151) in the first direction, and a left n−1 reflector (186A) and a right n−1 reflector (186B) are formed on both sides of the (n−1)th IDT electrode part 156 in the first direction. And a left n-th reflector (186A) and a right n-th reflector (186B) are formed on both sides of the n-th IDT electrode part (156) in the first direction, thereby forming a total of 2n reflectors. Additional IDT electrode parts may be formed between the first IDT electrode part (151) and the (n−1)th IDT electrode part (156). Next, referring to FIG. 6B, the first reflector (181B) and the second reflector (181A) are combined into a first common reflector (191) that is shared, and the reflectors between each IDT electrode part formed in the middle may be combined and shared, and finally, the (n−1)th reflector 186B and the nth reflector (187A) may be combined and shared as one (n−1)th common reflector (196).

Thus, the total reflectors are reduced to n+1 reflectors, consisting of n−1 common reflectors and 2 outermost reflectors. Before sharing the reflectors, there were 2n reflectors. After sharing, however, the number of reflectors reduces to n+1. This means the number of reflectors decreases by n−1, and the area of the piezoelectric substrate (100) required for the resonator is reduced accordingly.

Here, if the number of reflector electrodes of the n−1th electrode part 156 before forming the n−1th common reflector 196 is Nn−1, and the number of reflector electrodes of the n-th IDT electrode part 157 is Nn, the number Ns of reflector electrodes of the n−1th common reflector 196 satisfies the condition:

$$Min ( Nn - 1 , Nn ) \leq Ns \leq ( Nn - 1 + Nn )$$

In other words, the number of electrodes in the common reflector may be equal to or greater than the smaller of the two reflectors' electrode numbers, and it may be equal to or less than the total number of electrodes in both reflectors.

After forming the shared reflectors, the frequency characteristics and insertion loss of the resonator before and after sharing the reflectors are measured, confirming that the performance of the resonator does not degrade due to the shared reflectors.

FIGS. 7A and 7B are plan views showing a surface acoustic wave resonator according to another embodiment of the present invention, where the apertures is different. FIG. 7A shows n resonators formed separately, and FIG. 7B shows that all the n resonators share a common reflector.

If the second direction length of the reflector of the n−1th electrode part (156) before forming the n−1th common reflector (196) is Hn−1, and the second direction length of the reflector of the n-th IDT electrode part (157) is Hn, the length HSn−1 in the second direction of the n−1th common reflector 196 satisfies the condition:

$$Max ( Hn - 1 , Hn ) \leq HSn - 1$$

That is, when two resonators have different apertures, the common reflector's length may be greater than or equal to the length of the reflector of the larger aperture resonator between the two resonators.

The apertures is the region where the first and second IDT electrodes (130, 135) intersect, and this is where the surface acoustic wave is primarily transmitted, determining the resonator's characteristics. When the aperture is larger, the length of the IDT electrode part and the reflector in the second direction increases proportionally.

As with the previous cases, after the reflectors are shared, the frequency characteristics and insertion loss of the resonator are measured, and it is confirmed that the resonator's performance does not degrade despite sharing the reflectors.

FIGS. 8A and 8B are plan views showing a surface acoustic wave resonator according to another embodiment of the present invention, where the distance between electrodes differs. FIG. 8A shows n resonators formed separately, and FIG. 8B shows that all the n resonators share a common reflector.

Referring to FIG. 8B, if the distance between the IDT electrodes (130, 135) of the n−1th IDT electrode part (156) is Tn−1, and the distance between the IDT electrodes (130, 135) of the n-th IDT electrode part (157) is Tn, the distance between the reflector electrodes of the n−1th common reflector (196) and TSn−1 satisfies the condition:

$$Max ( Tn - 1 , Tn ) \leq TSn - 1$$

In other words, the distance between the electrodes of the common reflector can be greater than or equal to the distance between the two IDT electrodes on either side of the common reflector.

FIG. 9 shows the distance between the electrodes according to FIGS. 8A and 8B.

Referring to FIG. 9, the distance between the electrodes of the n−1 common reflector (196), denoted as TSn−1, is greater than the larger of the distances between the electrodes of the n−1 IDT electrode part (156) and the n IDT electrode part (157), i.e., Tn−1 and Tn. Although the graph in FIG. 9 does not explicitly show it, the distance between the electrodes of the n−1 common reflector (196), TSn−1, may also be equal to the larger of the two distances, Tn−1 and Tn.

By forming the resonators in this way, it is confirmed that sharing the reflectors does not degrade the resonator's characteristics, such as frequency response and insertion loss, after sharing the reflectors.

Although the present invention has been described as described above, those skilled in the art will recognize that the present invention may be implemented in other forms while maintaining the technical ideas and essential features of the present invention.

Although the scope of right of the present invention will be determined basically by the patent claims, it should be interpreted that all changes or modified forms derived from equivalent configurations, as well as the configurations directly derived from the description of the patent claims, are included in the scope of right of the present invention.

What is claimed is:

1. A resonator comprising:
a first and a second IDT electrode parts formed on a piezoelectric substrate and arranged parallel in a first direction;
a common reflector formed between the first and the second IDT electrode parts and shared by the first and the second IDT electrode parts; and
a first and a second reflectors formed on opposite sides of the common reflector, parallel to the first and the second IDT electrode part, respectively.

2. The resonator of claim 1, wherein the first or the second IDT electrode part includes a first and a second busbars that extends in the first direction and are spaced in the second direction perpendicular to the first direction, and a first and a second IDT electrodes extending in the second direction alternately from the first and the second busbars and spaced in the first direction.

3. The resonator of claim 1, wherein the reflector includes a pair of reflector busbars extend in the first direction and are spaced in the second direction perpendicular to the first direction, and a plurality of reflector electrodes extend in the second direction and are spaced in the first direction.

4. The resonator of claim 1, wherein, let the number of reflector electrodes of the first IDT electrode part before forming the common reflector be denoted as N1, and the number of reflector electrodes of the second IDT electrode part be denoted as N2, and the number of reflector electrodes of the first common reflector, denoted as Ns, satisfies the condition Min(N1, N2)≤Ns≤(N1+N2).

5. The resonator of claim 1, wherein, let the second direction length of the reflector of the first IDT electrode part before forming the common reflector be denoted as H1, and the second direction length of the reflector of the second IDT electrode part be denoted as H2, and the second direction length of the common reflector, denoted as HS, satisfies the condition Max(H1, H2)≤HS.

6. The resonator of claim 1, wherein, let the distance between the IDT electrodes of the first IDT electrode part be denoted as T1, and the distance between the IDT electrodes of the second IDT electrode part be denoted as T2, and the distance between the reflector electrodes of the common reflector, denoted as TS1, satisfies the condition Max(T1, T2)≤TS1.

7. A resonator comprising:
a first to nth IDT electrode parts formed on a piezoelectric substrate and arranged in parallel in a first direction, where n is a natural number greater than or equal to 3;
a first to (n−1) common reflector formed between the first to nth IDT electrode parts, and shared between two adjacent IDT electrode parts of the first to nth IDT electrode parts; and
a first and nth reflector formed on the opposite side of the common reflector, arranged in parallel to the first and nth IDT electrode parts, wherein the resonator has a common reflector.

8. The resonator of claim 7, wherein the first to nth IDT electrode parts include a first and a second busbars extend in the first direction and are spaced in a second direction perpendicular to the first direction, and a first and a second IDT electrodes alternately extending from the first and the second busbars in the second direction and spaced in the first direction.

9. The resonator of claim 7, wherein the reflector includes a pair of reflector busbars extend in the first direction and are spaced in the second direction perpendicular to the first direction, and a plurality of reflector electrodes that extend in the second direction and are spaced in the first direction.

10. The resonator of claim 7, wherein, let the number of reflector electrodes of the (n−1)th IDT electrode part before forming the common reflector be denoted as Nn−1, and the number of reflector electrodes of the nth IDT electrode part be denoted as Nn, and the number of reflector electrodes of the (n−1)th common reflector, denoted as Ns, satisfies the condition Min(Nn−1, Nn)≤Ns≤(Nn−1+Nn).

11. The resonator of claim 7, wherein, let the second direction length of the reflector of the (n−1)th IDT electrode part before forming the common reflector be denoted as Hn−1, and the second direction length of the reflector of the nth IDT electrode part be denoted as Hn, and the second direction length of the (n−1)th common reflector, denoted as HSn−1, satisfies the condition Max(Hn−1, Hn)≤HSn−1.

12. The resonator of claim 7, wherein, let the distance between the IDT electrodes of the (n−1)th IDT electrode part be denoted as Tn−1, and the distance between the IDT electrodes of the nth IDT electrode part be denoted as Tn, and the distance between the reflector electrodes of the common reflector, denoted as TSn−1, satisfies the condition Max(Tn−1, Tn)≤TSn−1.
